(19) United States
(12) Patent Application Publication
(10) Pub. No.: US 2017/0148752 A1
(43) Pub. Date: May 25, 2017

(54) CHIP PACKAGE AND MANUFACTURING METHOD THEREOF

(71) Applicant: XINTEC INC., Taoyuan City (TW)

(72) Inventors: Yen-Shih HO, Kaohsiung City (TW); Chia-Sheng LIN, Taoyuan City (TW); Po-Han LEE, Taipei City (TW); Wei-Luen SUEN, New Taipei City (TW)

(21) Appl. No.: 15/351,309

(22) Filed: Nov. 14, 2016

(30) Foreign Application Priority Data
Nov. 19, 2015 (TW) 104138318

(51) Int. Cl. H01L 23/00

(52) U.S. Cl. CPC H01L 24/05; H01L 24/02; H01L 24/13; H01L 24/03; H01L 2224/0239; H01L 2924/01013; H01L 2224/0401; H01L 2224/05024; H01L 2224/05082; H01L 2224/05124; H01L 2224/05166; H01L 2224/05184; H01L 2224/05155; H01L 2224/05144; H01L 2224/13026; H01L 2224/03464; H01L 2224/0214; H01L 2224/0215; H01L 2924/06

(57) ABSTRACT

A chip package includes a substrate, an isolation layer, a redistribution layer, a passivation layer, a first conductive layer, a second conductive layer, and a conductive structure. The isolation layer is located on the substrate. The redistribution layer is located on the isolation layer. The passivation layer is located on the isolation layer and the redistribution layer. The passivation layer has an opening, a wall surface that surrounds the opening, and a surface that faces away from the isolation layer. A portion of the redistribution layer is exposed through the opening. The first conductive layer is located on the redistribution layer that is in the opening, and extends to the wall surface and the surface of the passivation layer. The second conductive layer covers the first conductive layer. The conductive structure is located on the second conductive layer and protrudes from the passivation layer.

### RELATED APPLICATIONS

This application claims priority to Taiwan Application Serial Number 104138318, Nov. 19, 2015, which is herein incorporated by reference.

### BACKGROUND

Field of Invention

The present invention relates to a chip package and a manufacturing method of the chip package.

Description of Related Art

Generally, a bottom surface of a chip package has contacts used to electrically connect a printed circuit board. For example, conductive bumps or solder balls of a ball grid array (BGA) may be used as the contacts of the chip package.

In manufacture of a typical chip package, an isolation layer, a redistribution layer (RDL), an electroless nickel/immersion gold (ENIG) layer, a solder mask layer, and a solder ball may be formed on a bottom surface of a silicon substrate in sequence. In a subsequent test, the solder ball of the chip package is inspected by a ball level reliability test (BLRT). In this test, a thermal shock method is used, in which the chip package is placed in an environment from −40° C. to 85° C., and the stability of the solder ball on the redistribution layer is tested.

The solder ball is located in the opening of the patterned solder mask layer, and is electrically connected to the ENIG layer and the redistribution layer that are in the opening of the solder mask layer. As a result of such a design, the contact area of the solder ball and the ENIG layer is hard to be increased, so that the solder ball will be easily separated from the ENIG layer when suffering from a thermal shock. In addition, since the thickness of the redistribution layer and the thickness of the ENIG layer are thin, the solder ball is close to the isolation layer, such that the solder ball will be easily in contact with the isolation layer when suffering from a thermal shock.

### SUMMARY

An aspect of the present invention is to provide a chip package.

According to an embodiment of the present invention, a chip package includes a substrate, an isolation layer, a redistribution layer, a passivation layer, a first conductive layer, a second conductive layer, and a conductive structure. The isolation layer is located on the substrate. The redistribution layer is located on the isolation layer. The passivation layer is located on the isolation layer and the redistribution layer. The passivation layer has an opening, a wall surface that surrounds the opening, and a surface that faces away from the isolation layer. A portion of the redistribution layer is exposed through the opening. The first conductive layer is located on the redistribution layer that is in the opening and extends to the wall surface and the surface of the passivation layer. The second conductive layer covers the first conductive layer. The conductive structure is located on the second conductive layer and protrudes from the passivation layer.

Another aspect of the present invention is to provide a manufacturing method of a chip package.

According to an embodiment of the present invention, a manufacturing method of a chip package includes the following steps. An isolation layer is formed on a substrate. A redistribution layer is formed on the isolation layer. A patterned passivation layer is formed on the isolation layer and the redistribution layer, such that a portion of the redistribution layer is exposed through an opening of the passivation layer. A first conductive layer is formed on the redistribution layer that is in the opening, a wall surface of the passivation layer surrounding the opening, and a surface of the passivation layer facing away from the isolation layer. A second conductive layer is formed to cover the first conductive layer. A conductive structure is formed on the second conductive layer.

In the aforementioned embodiments of the present invention, the first conductive layer is located on the redistribution layer that is in the opening and extends to the wall surface of the passivation layer surrounding the opening and the surface of the passivation layer facing away from the isolation layer. Hence, after the second conductive layer covers the first conductive layer, the second conductive layer is also arranged along the first conductive layer that is in the opening of the passivation layer, the first conductive layer that is on the wall surface of the passivation layer, and the first conductive layer that is on the surface of the passivation layer. As a result, the conductive structure may be disposed on the second conductive layer, such that the contact area of the conductive structure and the second conductive layer may be increased, and the conductive structure will not be easily separated from the second conductive layer when suffering from a thermal shock.

Another aspect of the present invention is to provide a chip package.

According to an embodiment of the present invention, a chip package includes a substrate, an isolation layer, a supporting layer, a redistribution layer, a conductive layer, a passivation layer, and a conductive structure. The isolation layer is located on the substrate and has a surface that faces away from the substrate. The supporting layer is located on the surface of the isolation layer, and has a top surface that faces away from the isolation layer and a side surface that surrounds the top surface. The redistribution layer covers the top surface and the side surface of the supporting layer and extends to the surface of the isolation layer. The conductive layer covers the redistribution layer. The passivation layer is located on the isolation layer and the conductive layer, and has an opening and a surface that faces away from the isolation layer. A portion of the conductive layer is exposed through the opening. The conductive structure is located on the conductive layer that is in the opening and protrudes from the passivation layer.

Another aspect of the present invention is to provide a manufacturing method of a chip package.

According to an embodiment of the present invention, a manufacturing method of a chip package includes the following steps. An isolation layer is formed on a substrate. A supporting layer is formed on the isolation layer. A redistribution layer is formed to cover a top surface of the supporting layer facing away from the isolation layer and a side surface of the supporting layer surrounding the top surface. The redistribution layer extends to a surface of the isolation layer facing away from the substrate. A conductive layer is formed to cover the redistribution layer. A patterned passivation layer is formed on the isolation layer and the conductive layer, such that a portion of the conductive layer is exposed through an opening of the passivation layer. A conductive structure is formed on the conductive layer that is in the opening.

In the aforementioned embodiments of the present invention, the supporting layer is located on the surface of the isolation layer, and the redistribution layer covers the top surface and the side surface of the supporting layer and extends to the surface of the isolation layer. Hence, after the conductive layer covers the redistribution layer, the conductive layer is also arranged along the redistribution layer that is on the top surface and the side surface of the supporting layer and the redistribution layer that is on the surface of the isolation layer. As a result, the conductive structure may be disposed on the conductive layer that is in the opening. Through the configuration of the supporting layer, a distance between the conductive structure and the isolation layer is increased, such that the conductive structure will not be easily in contact with the isolation layer when suffering from a thermal shock.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a cross-sectional view of a chip package according to one embodiment of the present invention;

FIG. 2 is a flow chart of a manufacturing method of a chip package according to one embodiment of the present invention;

FIG. 3 is a cross-sectional view of an isolation layer after being formed on a substrate according to one embodiment of the present invention;

FIG. 4 is a cross-sectional view of a redistribution layer after being formed on the isolation layer shown in FIG. 3;

FIG. 5 is a cross-sectional view of a passivation layer after being formed on the isolation layer and the redistribution layer shown in FIG. 4;

FIG. 6 is a cross-sectional view of a first conductive layer after being formed on the redistribution layer and the passivation layer shown in FIG. 5;

FIG. 7 is a cross-sectional view of a second conductive layer after being formed on the first conductive layer shown in FIG. 6;

FIG. 8 is a cross-sectional view of a chip package according to one embodiment of the present invention;

FIG. 9 is a cross-sectional view of a chip package according to one embodiment of the present invention;

FIG. 10 is a flow chart of a manufacturing method of a chip package according to one embodiment of the present invention;

FIG. 11 is a cross-sectional view of a supporting layer after being formed on an isolation layer according to one embodiment of the present invention;

FIG. 12 is a cross-sectional view of a redistribution layer and a conductive layer after being formed on the supporting layer and the isolation layer shown in FIG. 11;

FIG. 13 is a cross-sectional view of a passivation layer after being formed on the isolation layer and the conductive layer shown in FIG. 12; and

FIG. 14 is a cross-sectional view of a chip package according to one embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

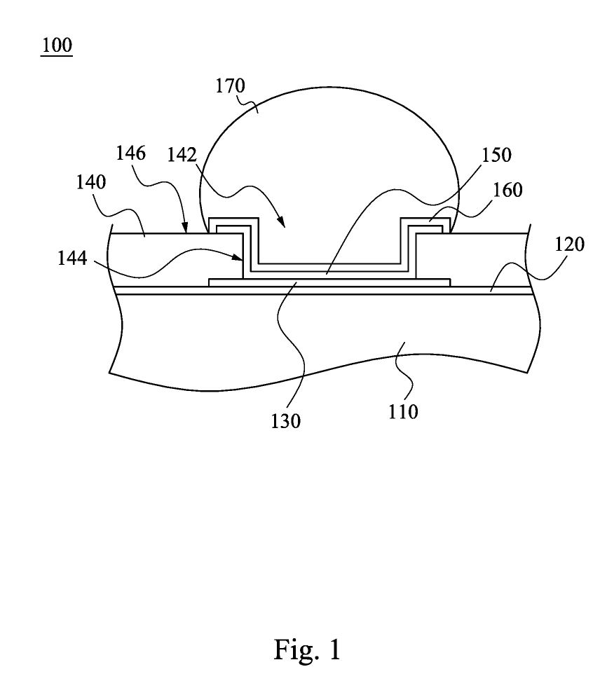

FIG. 1 is a cross-sectional view of a chip package 100 according to one embodiment of the present invention. As shown in FIG. 1, the chip package 100 includes a substrate 110, an isolation layer 120, a redistribution layer 130, a passivation layer 140, a first conductive layer 150, a second conductive layer 160, and a conductive structure 170. The isolation layer 120 is located on the substrate 110. The redistribution layer 130 is located on the isolation layer 120. The passivation layer 140 is located on the isolation layer 120 and the redistribution layer 130. The passivation layer 140 has an opening 142, a wall surface 144 that surrounds the opening 142, and a surface 146 that faces away from the isolation layer 120. A portion of the redistribution layer 130 may be exposed through the opening 142 of the passivation layer 140. The first conductive layer 150 is located on the redistribution layer 130 that is in the opening 142. The first conductive layer 150 extends to the wall surface 144 and the surface 146 of the passivation layer 140. The second conductive layer 160 covers the first conductive layer 150. The conductive structure 170 is located on the second conductive layer 160 and protrudes from the passivation layer 140.

In this embodiment, the substrate 110 may be made of a material including silicon, such as a semiconductor chip. The redistribution layer 140 may be made of a material including aluminum. The passivation layer 140 may be made of a material including epoxy, such as a solder mask layer. The first conductive layer 150 may be made of a material including aluminum or a titanium-tungsten (TiW) alloy, and the thickness of the first conductive layer 150 may be in a range from about 2 μm to about 4 μm, such as 3 μm. Furthermore, the second conductive layer 160 may be made of a material including a nickel-gold alloy. The first conductive layer 150 may be used as an under bump metallurgy (UBM) layer, and the second conductive layer 160 may be used as a diffusion barrier layer. The conductive structure 170 may be a solder ball of a ball grid array or a conductive bump, but the shape or material of the conductive structure 170 of the present invention is not limited thereto.

Since the first conductive layer 150 is located on the redistribution layer 130 that is in the opening 142 of the passivation layer 140 and extends to the wall surface 144 and the surface 146 of the passivation layer 140, the second conductive layer 160 is also arranged along the first conductive layer 150 that is in the opening 142 of the passivation layer 140 and on the wall surface 144 and the surface 146 of the passivation layer 140 after the second conductive layer 160 covers the first conductive layer 150. As a result, the conductive structure 170 may be disposed on the second conductive layer 160, such that the contact area of the conductive structure 170 and the second conductive layer 160 may be increased. Hence, the conductive structure 170 of the chip package 100 of the present invention will not be easily separated from the second conductive layer 160 when suffering from a thermal shock.

It is to be noted that the materials and the connection relationships of the elements described above will not be repeated in the following description. In the following description, a manufacturing method of the chip package 100 shown in FIG. 1 will be described.

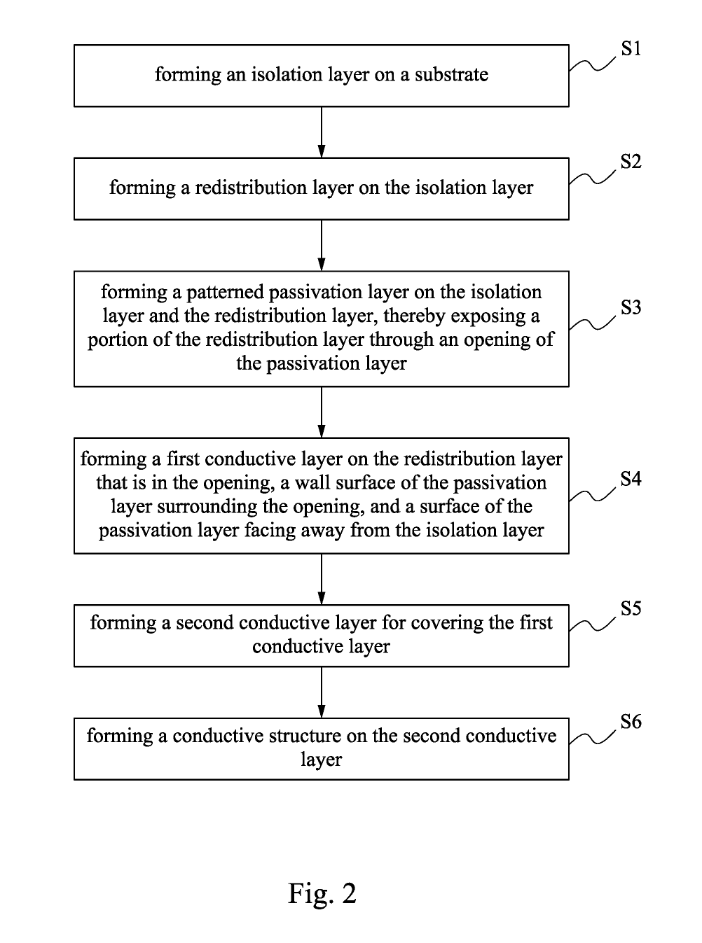

FIG. 2 is a flow chart of a manufacturing method of a chip package according to one embodiment of the present invention. The manufacturing method of the chip package includes the following steps. In step S1, an isolation layer is formed on a substrate. Thereafter, in step S2, a redistribution layer is formed on the isolation layer. Next, in step S3, a patterned passivation layer is formed on the isolation layer and the redistribution layer, such that a portion of the redistribution layer is exposed through an opening of the passivation layer. Subsequently, in step S4, a first conductive layer is formed on the redistribution layer that is in the opening, a wall surface of the passivation layer surrounding the opening, and a surface of the passivation layer facing away from the isolation layer. Afterwards, in step S5, a second conductive layer is formed to cover the first conductive layer. Finally, in step S6, a conductive structure is formed on the second conductive layer. In the following description, the aforesaid steps of the manufacturing method will be explained.

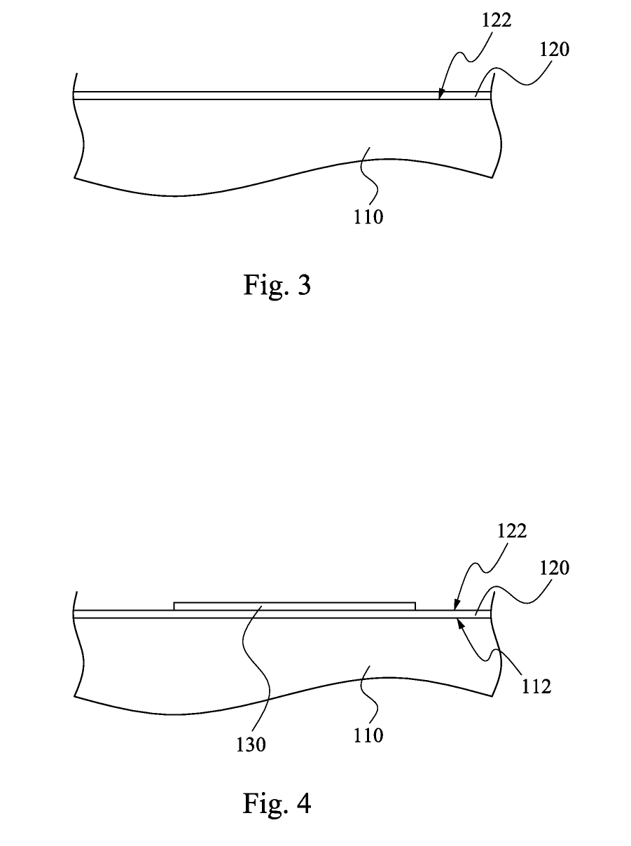

FIG. 3 is a cross-sectional view of the isolation layer 120 after being formed on the substrate 110 according to one embodiment of the present invention. FIG. 4 is a cross-sectional view of the redistribution layer 130 after being formed on the isolation layer 120 shown in FIG. 3. As shown in FIG. 3 and FIG. 4, the isolation layer 120 may be formed on a surface 112 of the substrate 110 by utilizing chemical vapor deposition (CVD). The surface 112 is a back surface of the substrate 110. The isolation layer 120 may be made of a material including silicon dioxide, but the present invention is not limited in this regard. After the isolation layer 120 is formed, the patterned redistribution layer 130 may be formed on a surface 122 of the isolation layer 120 facing away from the substrate 110. The redistribution layer 130 may be formed on the isolation layer 120 by utilizing physical vapor deposition (PVD), such as a sputtering process.

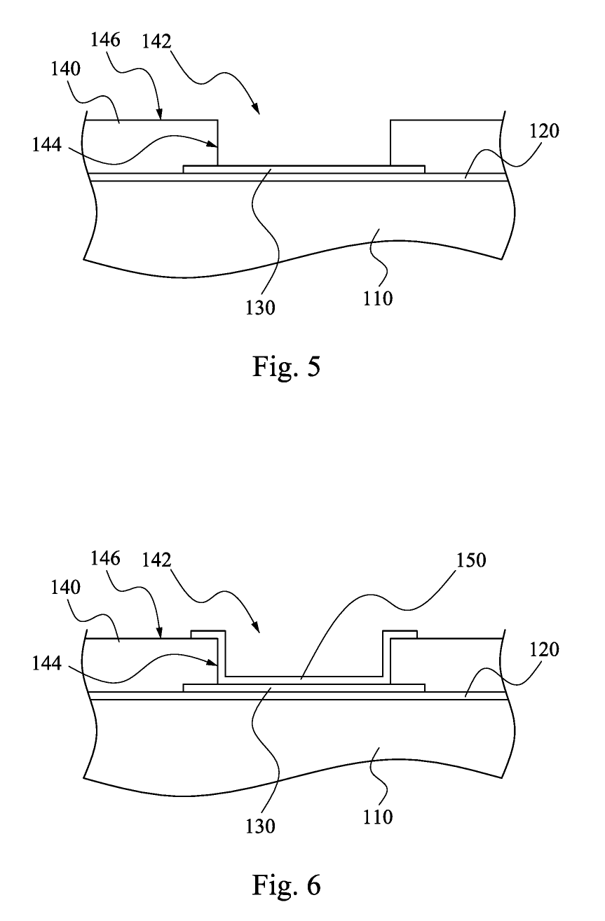

FIG. 5 is a cross-sectional view of the passivation layer 140 after being formed on the isolation layer 120 and the redistribution layer 130 shown in FIG. 4. As shown in FIG. 4 and FIG. 5, after the redistribution layer 130 is formed, the patterned passivation layer 140 may be formed on the isolation layer 120 and the redistribution layer 130, such that the passivation layer 140 has the opening 142, and a portion of the redistribution layer 130 is exposed through the opening 142 of the passivation layer 140.

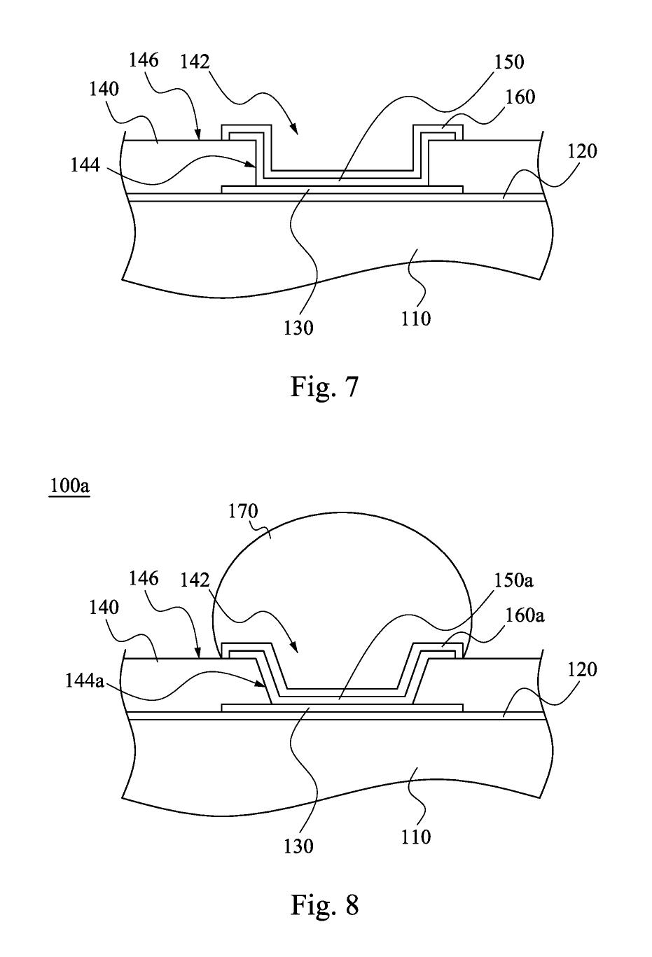

FIG. 6 is a cross-sectional view of the first conductive layer 150 after being formed on the redistribution layer 130 and the passivation layer 140 shown in FIG. 5. FIG. 7 is a cross-sectional view of the second conductive layer 160 after being formed on the first conductive layer 150 shown in FIG. 6. As shown in FIG. 6 and FIG. 7, after the patterned passivation layer 140 is formed, the first conductive layer 150 may be formed on the redistribution layer 130 that is in the opening 142 of the passivation layer 140 and on the wall surface 144 and the surface 146 of the passivation layer 140. Thereafter, the second conductive layer 160 may be formed to cover the first conductive layer 150. In this embodiment, the second conductive layer 160 may be formed through electroless plating. For example, the second conductive layer 160 is an electroless nickel/immersion gold (ENIG) layer.

As shown in FIG. 1 and FIG. 7, after the second conductive layer 160 is formed, the conductive structure 170 may be formed on the second conductive layer 160, thereby obtaining the chip package 100.

FIG. 8 is a cross-sectional view of a chip package 100a according to one embodiment of the present invention. The chip package 100a includes the substrate 110, the isolation layer 120, the redistribution layer 130, the passivation layer 140, a first conductive layer 150a, a second conductive layer 160a, and the conductive structure 170. The difference between this embodiment and the embodiment shown in FIG. 1 is that a wall surface 144a of the passivation layer 140 of the chip package 100a is an oblique surface, and an obtuse angle is included between the oblique surface and the redistribution layer 130. As a result of such a design, the first conductive layer 150a and the second conductive layer 160a may be prevented from being broken due to making a turn on the passivation layer 140 and the redistribution layer 130.

In the following description, other types of chip packages will be described.

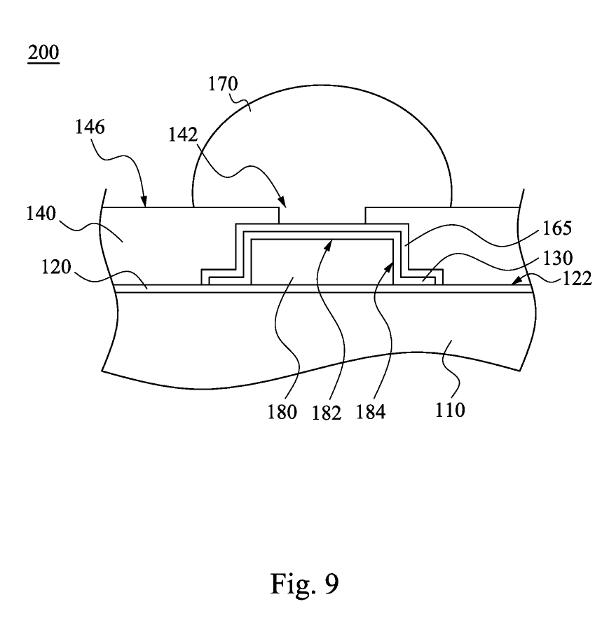

FIG. 9 is a cross-sectional view of a chip package 200 according to one embodiment of the present invention. The chip package 200 includes a substrate 110, an isolation layer 120, a supporting layer 180, a redistribution layer 130, a conductive layer 165, a passivation layer 140, and a conductive structure 170. The isolation layer 120 is located on the substrate 110 and has a surface 122 that faces away from the substrate 110. The supporting layer 180 is located on the surface 122 of the isolation layer 120. Moreover, the supporting layer 180 has a top surface 182 that faces away from the isolation layer 120 and a side surface 184 that surrounds the top surface 182. In this embodiment, the supporting layer 180 may be made of a material including polymer, but the present invention is not limited in this regard. The redistribution layer 130 covers the top surface 182 and the side surface 184 of the supporting layer 180 and extends to the surface 122 of the isolation layer 120. The conductive layer 165 covers the redistribution layer 130. The passivation layer 140 is located on the isolation layer 120 and the conductive layer 165. The passivation layer 140 has an opening 142 and a surface 146 that faces away from the isolation layer 120. A portion of the conductive layer 165 is exposed through the opening 142 of the passivation layer 140. The conductive structure 170 is located on the conductive layer 165 that is in the opening 142 and protrudes from the passivation layer 140.

Since the supporting layer 180 is located on the surface 122 of the isolation layer 120, and the redistribution layer 130 covers the top surface 182 and the side surface 184 of the supporting layer 180 and extends to the surface 122 of the isolation layer 120, the conductive layer 165 is also arranged along the redistribution layer 130 that is on the top surface 182 and the side surface 184 of the supporting layer 180 and on the surface 122 of the isolation layer 120 after the conductive layer 165 covers the redistribution layer 130. As a result, the conductive structure 170 may be disposed on the conductive layer 165 that is in the opening 142. Through the configuration of the supporting layer 180, a distance between the conductive structure 170 and the isolation layer 120 is increased, such that the conductive structure 170 will not be easily in contact with the isolation layer 120 when suffering from a thermal shock.

In the following description, a manufacturing method of the chip package 200 shown in FIG. 9 will be described.

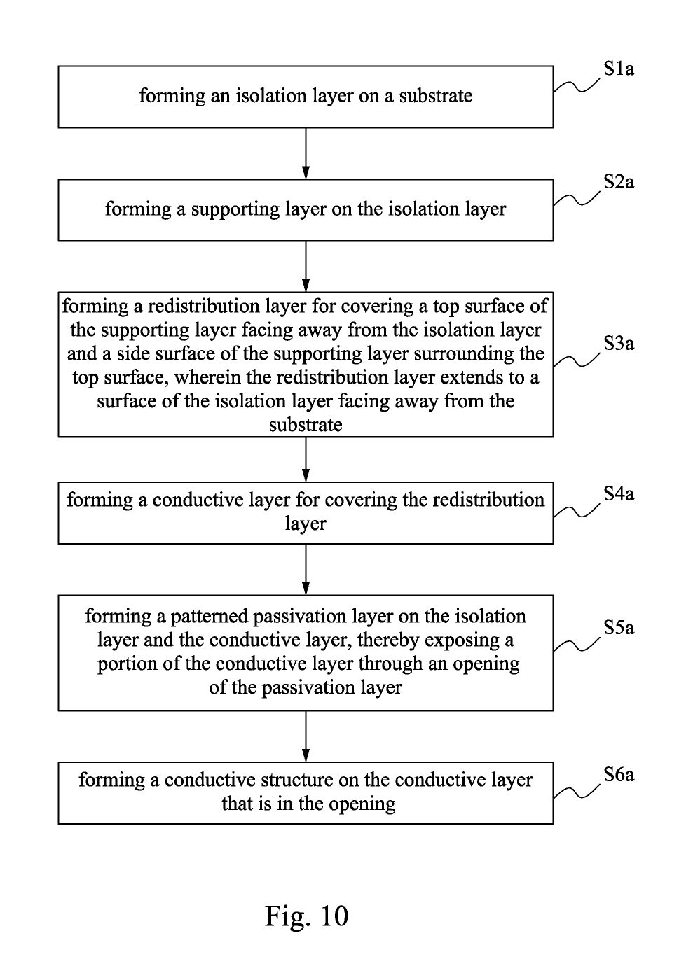

FIG. 10 is a flow chart of a manufacturing method of a chip package according to one embodiment of the present invention. The manufacturing method of the chip package includes the following steps. In step S1a, an isolation layer is formed on a substrate. Thereafter, in step S2a, a supporting layer is formed on the isolation layer. Next, in step S3a, a redistribution layer is formed to cover a top surface of the supporting layer facing away from the isolation layer and a side surface of the supporting layer surrounding the top surface, and the redistribution layer extends to a surface of the isolation layer facing away from the substrate. Subsequently, in step S4a, a conductive layer is formed to cover the redistribution layer. Afterwards, in step S5a, a patterned passivation layer is formed on the isolation layer and the conductive layer, such that a portion of the conductive layer is exposed through an opening of the passivation layer. Finally, in step S6a, a conductive structure is formed on the conductive layer that is in the opening. In the following description, the aforesaid steps of the manufacturing method will be explained.

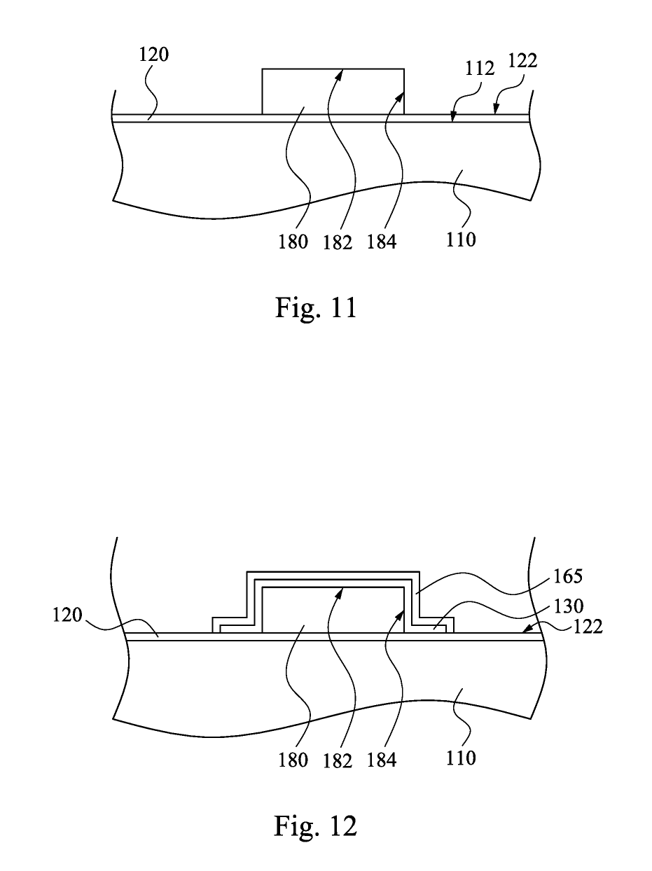

FIG. 11 is a cross-sectional view of the supporting layer 180 after being formed on the isolation layer 120 according to one embodiment of the present invention. FIG. 12 is a cross-sectional view of the redistribution layer 130 and the conductive layer 165 after being formed on the supporting layer 180 and the isolation layer 120 shown in FIG. 11. As shown in FIG. 11 and FIG. 12, after the isolation layer 120 is formed on the surface 112 of the substrate 110, the supporting layer 180 may be formed on the surface 122 of the isolation layer 120. Thereafter, the redistribution layer 130 may be formed to cover the top surface 182 and the side surface 184 of the supporting layer 180, and the redistribution layer 130 extends to the surface 122 of the isolation layer 120. After the redistribution layer 130 is formed, the conductive layer 165 may be formed to cover the redistribution layer 130 through electroless plating.

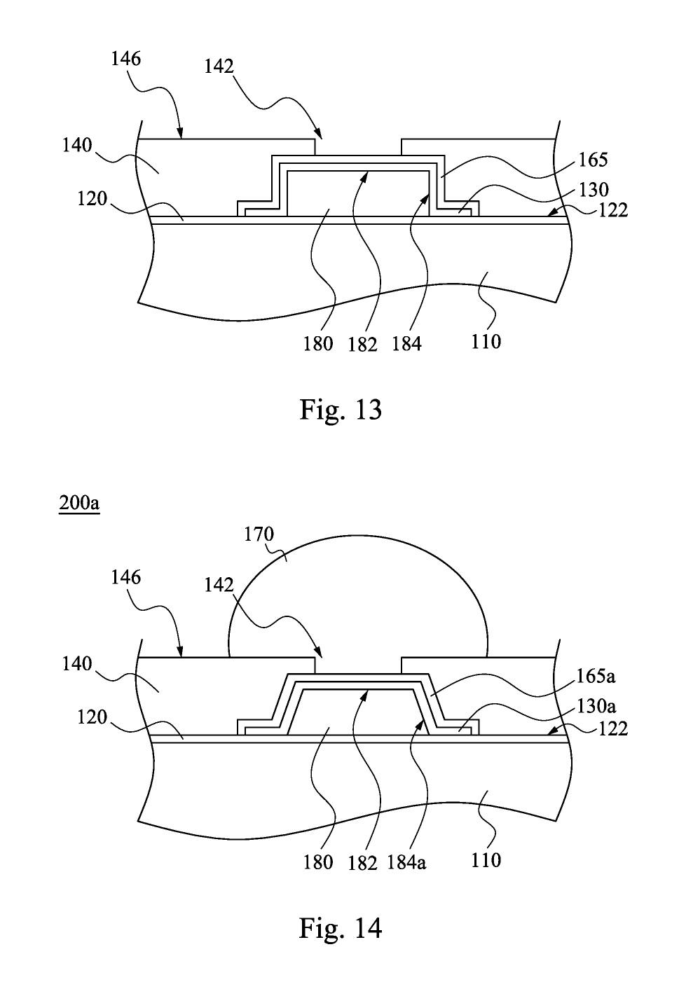

FIG. 13 is a cross-sectional view of the passivation layer 140 after being formed on the isolation layer 120 and the conductive layer 165 shown in FIG. 12. As shown in FIG. 12 and FIG. 13, after the conductive layer 165 is formed, the patterned passivation layer 140 may be formed on the isolation layer 120 and the conductive layer 165, such that a portion of the conductive layer 165 may be exposed through the opening 142 of the passivation layer 140. Thereafter, the conductive structure 170 (see FIG. 9) may be formed on the conductive layer 165 that is in the opening 142, thereby obtaining the chip package 200 of FIG. 9.

FIG. 14 is a cross-sectional view of a chip package 200a according to one embodiment of the present invention. The chip package 200a includes the substrate 110, the isolation layer 120, the supporting layer 180, a redistribution layer 130a, a conductive layer 165a, the passivation layer 140, and the conductive structure 170. The difference between this embodiment and the embodiment shown in FIG. 9 is that a side surface 184a of the supporting layer 180 is an oblique surface, and an obtuse angle is included between the oblique surface and the isolation layer 120. As a result of such a design, the redistribution layer 130a and the conductive layer 165a may be prevented from being broken due to making a turn on the supporting layer 180 and the isolation layer 120.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A chip package, comprising:
a substrate;
an isolation layer located on the substrate;
a redistribution layer located on the isolation layer;
a passivation layer located on the isolation layer and the redistribution layer, the passivation layer having an opening, a wall surface that surrounds the opening, and a surface that faces away from the isolation layer, wherein a portion of the redistribution layer is exposed through the opening;
a first conductive layer located on the redistribution layer that is in the opening, wherein the first conductive layer extends to the wall surface and the surface of the passivation layer;
a second conductive layer covering the first conductive layer; and
a conductive structure located on the second conductive layer and protruding from the passivation layer.

2. The chip package of claim 1, wherein the redistribution layer is made of a material comprising aluminum.

3. The chip package of claim 1, wherein the first conductive layer is made of a material comprising aluminum or a titanium-tungsten alloy.

4. The chip package of claim 1, wherein a thickness of the first conductive layer is in a range from 2 μm to 4 μm.

5. The chip package of claim 1, wherein the second conductive layer is made of a material comprising a nickel-gold alloy.

6. The chip package of claim 1, wherein the conductive structure is a solder ball or a conductive bump.

7. The chip package of claim 1, wherein the wall surface of the passivation layer is an oblique surface, and an obtuse angle is included between the oblique surface and the redistribution layer.

8. A manufacturing method of a chip package, the manufacturing method comprising:
forming an isolation layer on a substrate;
forming a redistribution layer on the isolation layer;
forming a patterned passivation layer on the isolation layer and the redistribution layer, thereby exposing a portion of the redistribution layer through an opening of the passivation layer;
forming a first conductive layer on the redistribution layer that is in the opening, a wall surface of the passivation layer surrounding the opening, and a surface of the passivation layer facing away from the isolation layer;
forming a second conductive layer for covering the first conductive layer; and
forming a conductive structure on the second conductive layer.

9. The manufacturing method of the chip package of claim 8, wherein the second conductive layer is formed through electroless plating.

10. A chip package, comprising:
a substrate;
an isolation layer located on the substrate and having a surface that faces away from the substrate;
a supporting layer located on the surface of the isolation layer and having a top surface that faces away from the isolation layer and a side surface that surrounds the top surface;
a redistribution layer covering the top surface and the side surface of the supporting layer and extending to the surface of the isolation layer;
a conductive layer covering the redistribution layer;
a passivation layer located on the isolation layer and the conductive layer, the passivation layer having an opening and a surface that faces away from the isolation layer, wherein a portion of the conductive layer is exposed through the opening; and
a conductive structure located on the conductive layer that is in the opening, the conductive structure protruding from the passivation layer.

11. The chip package of claim 10, wherein the supporting layer is made of a material comprising polymer.

12. The chip package of claim 10, wherein the redistribution layer is made of a material comprising aluminum.

13. The chip package of claim 10, wherein the conductive layer is made of a material comprising a nickel-gold alloy.

14. The chip package of claim 10, wherein the conductive structure is a solder ball or a conductive bump.

15. The chip package of claim 10, wherein the side surface of the supporting layer is an oblique surface, and an obtuse angle is included between the oblique surface and the isolation layer.

16. A manufacturing method of a chip package, the manufacturing method comprising:
forming an isolation layer on a substrate;
forming a supporting layer on the isolation layer;
forming a redistribution layer for covering a top surface of the supporting layer facing away from the isolation layer and a side surface of the supporting layer surrounding the top surface, wherein the redistribution layer extends to a surface of the isolation layer facing away from the substrate;
forming a conductive layer for covering the redistribution layer;
forming a patterned passivation layer on the isolation layer and the conductive layer, thereby exposing a portion of the conductive layer through an opening of the passivation layer; and
forming a conductive structure on the conductive layer that is in the opening.

17. The manufacturing method of the chip package of claim 16, wherein the conductive layer is formed through electroless plating.
